(19) United States
(12) Patent Application Publication
(10) Pub. No.: US 2012/0038622 A1
(43) Pub. Date: Feb. 16, 2012

(54) LEVEL SHIFTER, METHOD FOR GENERATING CLOCK-PULSE OUTPUT SIGNAL AND CORRESPONDING FLAT DISPLAY DEVICE

(75) Inventors: Jing-Teng CHENG, Hsin-Chu (TW); Chao-Ching HSU, Hsin-Chu (TW)

(73) Assignee: AU OPTRONICS CORP., HSINCHU (TW)

(21) Appl. No.: 13/108,102

(22) Filed: May 16, 2011

(30) Foreign Application Priority Data
Aug. 11, 2010 (TW) 099126820

(51) Int. Cl. H03L 5/00; G09G 5/00

(52) U.S. Cl. 345/213; 327/333

(57) ABSTRACT

A level shifter includes at least one level shift unit for generating a corresponding clock-pulse output signal. The level shift unit receives a corresponding clock-pulse input signal. The clock-pulse output signal successively shares charges with respective auxiliary reference voltage sources to pull up a voltage level of the clock-pulse output signal from the second reference voltage to the first reference voltage. Alternatively, the clock-pulse output signal successively shares charges with respective auxiliary reference voltage sources to pull down the voltage level of the clock-pulse output signal from the first reference voltage to the second reference voltage.

### TECHNICAL FIELD

The present invention relates to a display technology, and more particularly to a level shifter, a method for generating a clock-pulse output signal and a corresponding flat display device.

### BACKGROUND

With increasing development of science and technology, flat panel display devices (e.g. liquid crystal display devices) gradually replace cathode ray tube (CRT) display devices because the flat panel display devices have many benefits such as light weightiness, slimness and low radiation. A typical liquid crystal display device comprises a display substrate, a circuit board, a gate driving circuit and a source driving circuit. The gate driving circuit and the source driving circuit are formed on the display substrate. A timing controller is mounted on the circuit board for providing plural control signals to the gate driving circuit and the source driving circuit. The gate driving circuit is used to drive plural gate lines on the display substrate. The source driving circuit is used to output image signals to plural data lines on the display substrate. Generally, the gate driving circuit and the source driving circuit are mounted on the display substrate by a tape carrier package (TCP) technology or a chip on glass (COG) packaging technology. Furthermore, the gate driving circuit may be directly formed on the display substrate to define a so-called gate-on-array circuit (GOA circuit). Moreover, the GOA circuit comprises a shift register. The shift register comprises plural cascade-connected stages for generating plural gate driving pulses to successively enable the gate lines on the display substrate.

Conventionally, in the GOA circuit of two-phase array, the level shifter is disposed on the circuit board to generate voltages required for two clock-pulse signals and provide energy required for the gate driving pulses. Since the difference between the voltage amplitudes of these two clock-pulse signals (i.e. the voltage difference between the high voltage level and the low voltage level) is very high and the stage number of the level shifter is too large, the parasitic capacitance and the power consumption are considerably high.

For solving the above drawbacks, a charge-sharing technology is used to reduce the power consumption of the level shifter. The two clock-pulse signals have opposite polarities. According to the current charge-sharing technology, before the polarities of these two clock-pulse signals are switched, these two clock-pulse signals are connected with each other to share charges to change the voltage levels to the medium levels. Then, the voltage levels are respectively amplified to the target voltage levels by the output buffer of the level shifter. However, since the polarities of these two clock-pulse signals are opposite, if one of the clock-pulse signals is increased, the other clock-pulse signal should be decreased. In other words, since these two clock-pulse signals fail to be simultaneously at the high voltage-level state or the low voltage-level state, the flexibility of designing this level shifter is undesired.

Moreover, when the level shifter is applied to other multi-phase (e.g. four-phase) GOA circuit, if the enabling periods of the multi-phase clock-pulse signals are partially overlapped with each other, the charge-sharing technology of the above two-phase clock-pulse signals fails to be applied to the multi-phase clock-pulse signals. Under this circumstance, the power consumption of the multi-phase level shifter is relatively large.

### SUMMARY

The present invention provides a level shifter with reduced power consumption.

The present invention also provides a method for generating a clock-pulse output signal in order to expand the application and reduce power consumption.

Moreover, the present invention further provides a flat display device with reduced power consumption.

In accordance with an aspect, the present invention provides a level shifter. The level shifter includes at least one level shift unit. The at least one level shift unit generates a corresponding clock-pulse output signal. The at least one level shift unit includes an amplifier and a controlling circuit. The amplifier includes an input terminal for receiving a clock-pulse input signal, a positive power terminal for receiving a first reference voltage, a negative power terminal for receiving a second reference voltage, and an output terminal, wherein the first reference voltage is higher than the second reference voltage. The controlling circuit is used for outputting the clock-pulse output signal from an output terminal of the controlling circuit. The controlling circuit includes a control switch and plural auxiliary control switches. The control switch is electrically coupled between the output terminal of the amplifier and the output terminal of the controlling circuit. The plural auxiliary control switches are electrically coupled between respective auxiliary reference voltage sources and the output terminal of the controlling circuit. The control switch and the plural auxiliary control switches are turned on at different time points according to the control signal, so that the clock-pulse output signal successively shares charges with respective auxiliary reference voltage sources to pull up a voltage level of the clock-pulse output signal from the second reference voltage to the first reference voltage, or the clock-pulse output signal successively shares charges with respective auxiliary reference voltage sources to pull down the voltage level of the clock-pulse output signal from the first reference voltage to the second reference voltage.

In accordance with another aspect, the present invention provides a clock-pulse output signal generating method for use in a level shifter of a gate-on-array circuit. The clock-pulse output signal generating method includes steps of receiving a clock-pulse input signal, and sharing charges between the clock-pulse output signal corresponding to the clock-pulse input signal and respective auxiliary reference voltage sources to pull up a voltage level of the clock-pulse output signal to a first reference voltage, or sharing charges between the clock-pulse output signal and the respective auxiliary reference voltage sources to pull down the voltage level of the clock-pulse output signal to a second reference voltage.

In accordance with a further aspect, the present invention provides a flat display device. The flat display device includes a timing controller, a level shifter and a gate-on-array shift register. The timing controller is used for generating a control signal and at least one clock-pulse input signal. The level shifter is used for receiving the control signal and the at least one clock-pulse input signal, and generating at least one clock-pulse output signal corresponding to the at least one clock-pulse input signal. The gate-on-array shift register is used for receiving the at least one clock-pulse output signal, thereby generating plural gate driving pulses. The level shifter includes at least one level shift unit. Each level shift unit includes an amplifier and a controlling circuit. The amplifier includes an input terminal receiving a corresponding clock-pulse input signal of the at least one clock-pulse input signal, a positive power terminal receiving a first reference voltage, a negative power terminal receiving a second reference voltage, and an output terminal. The controlling circuit is used for outputting the clock-pulse output signal from an output terminal of the controlling circuit. The controlling circuit includes a control switch electrically coupled between the output terminal of the amplifier and the output terminal of the controlling circuit, and plural auxiliary control switches electrically coupled between respective auxiliary reference voltage sources and the output terminal of the controlling circuit. The control switch and the plural auxiliary control switches are turned on at different time points according to the control signal, so that the clock-pulse output signal successively shares charges with respective auxiliary reference voltage sources to pull up a voltage level of the clock-pulse output signal from the second reference voltage to the first reference voltage, or the clock-pulse output signal successively shares charges with the respective auxiliary reference voltage sources to pull down the voltage level of the clock-pulse output signal from the first reference voltage to the second reference voltage.

In an embodiment, at least one of the first reference voltage, the second reference voltage and the auxiliary reference voltage sources is provided by a corresponding floating capacitor.

In an embodiment, the enabling periods of plural clock-pulse output signals generated from plural level shift units are not overlapped with each other. Alternatively, the enabling periods of plural clock-pulse output signals generated from plural level shift units are partially overlapped with each other.

The level shifter of the present invention utilizes each level shift unit to amplify the clock-pulse input signal and shares charges by plural auxiliary reference voltage sources to obtain a corresponding clock-pulse output signal. Since the clock-pulse output signal successively shares charges with different auxiliary reference voltage sources, the power consumption is largely reduced and the power-saving efficacy is achieved. Moreover, since the level shifter and the charge-sharing technology of the present invention can be applied to a two-phase GOA circuit or more-phase (e.g. three-phase or four-phase) GOA circuit, the applications of the present invention are broadened.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 is a schematic functional block diagram illustrating a flat panel display device according to an embodiment of the present invention;

FIG. 2 is a schematic circuit diagram illustrating an exemplary level shift unit of the present invention;

FIG. 3 is a schematic timing waveform diagram illustrating associated signals processed in the level shift unit of FIG. 2;

FIG. 4 is a schematic timing waveform diagram illustrating associated signals processed in a level shifter of a four-phase GOA circuit according to an embodiment the present invention;

FIG. 5 is a schematic timing waveform diagram illustrating associated signals processed in a level shifter of a four-phase GOA circuit according to another embodiment of the present invention; and

FIG. 6 is a schematic circuit diagram illustrating another exemplary level shift unit of the present invention.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

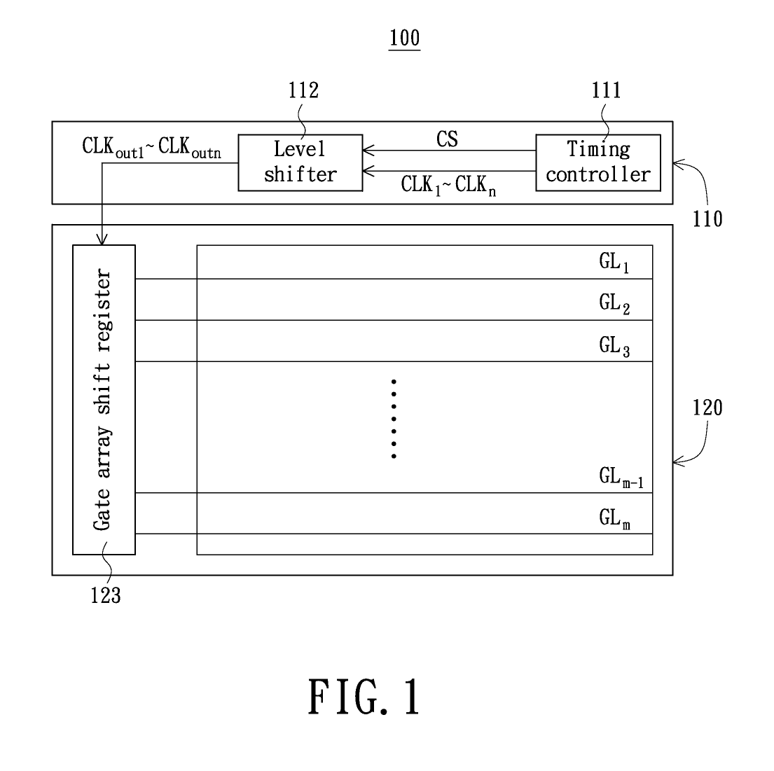

FIG. 1 is a schematic functional block diagram illustrating a flat panel display device according to an embodiment of the present invention. As shown in FIG. 1, the flat panel display device 100 comprises a circuit board 110 and a display substrate 120. A timing controller 111 and a level shifter 112 are mounted on the circuit board 110. The display zone (not shown) of the display substrate 120 comprises plural gate lines GL₁˜GLₘ. The periphery zone (not shown) of the display substrate 120 comprises a gate array shift register 123. The timing controller 111 is used for generating at least one clock-pulse input signal CLK₁˜CLKₙ and a control signal CS. The level shifter 112 is used for receiving and processing the clock-pulse input signal CLK₁˜CLKₙ and the control signal CS, thereby outputting corresponding clock-pulse output signals CLKₒᵤₜ₁˜CLKₒᵤₜₙ. In addition, the clock-pulse output signals CLKₒᵤₜ₁˜CLKₒᵤₜₙ are received by the gate array shift register 123. In response to the clock-pulse output signals CLKₒᵤₜ₁˜CLKₒᵤₜₙ, the gate array shift register 123 generates plural gate driving pulses to successively enable the gate lines GL₁˜GLₘ of the display substrate 120. The level shifter 112 comprises at least one level shift unit (not shown). Each level shift unit receives the control signal CS and a clock-pulse input signal (e.g. CLKₙ). According to the control signal CS, the level shift unit processes the clock-pulse input signal (e.g. CLKₙ), thereby generating a corresponding clock-pulse output signal (e.g. CLKₒᵤₜₙ).

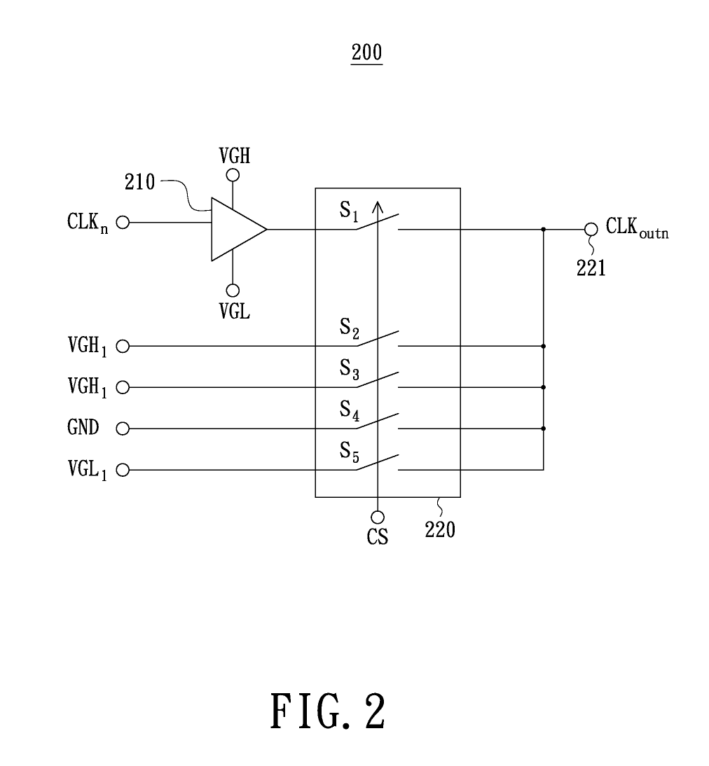

FIG. 2 is a schematic circuit diagram illustrating an exemplary level shift unit of the present invention. As shown in FIG. 2, the level shift unit 200 comprises an amplifier 210 and a controlling circuit 220. The amplifier 210 comprises an input terminal, a positive power terminal, a negative power terminal and an output terminal. The input terminal of the amplifier 210 receives the clock-pulse input signal CLKₙ. The positive power terminal receives a first reference voltage VGH. The negative power terminal receives a second reference voltage VGL. The first reference voltage VGH is higher than the second reference voltage VGL. The controlling circuit 220 is electrically connected with the output terminal of the amplifier 210 and selectively connected to plural auxiliary reference voltage sources (e.g. VGL₁, GND, VGH₁ and VGH₂) such that the clock-pulse output signal CLKₒᵤₜₙ can be outputted from the output terminal 221 of the controlling circuit 220 corresponding to the currently connected auxiliary reference voltage source. In this embodiment, the controlling circuit 220 comprises a control switch S₁ and plural auxiliary control switches S₂˜S₅. The control switch S₁ is electrically coupled between the output terminal of the amplifier 210 and the output terminal 221 of the controlling circuit 220. The auxiliary control switches S₂˜S₅ are electrically coupled between respective auxiliary reference voltage sources and the output terminal 221 of the controlling circuit 220. The voltage level of each of the auxiliary reference voltage sources VGL₁, GND, VGH₁ and VGH₂ is ranged between the first reference voltage VGH and the second reference voltage VGL. In addition, the voltage levels of the auxiliary reference voltage sources VGL₁, GND, VGH₁ and VGH₂ are different. In this embodiment, the voltage levels of the second reference voltage VGL and the auxiliary reference voltage source VGL₁ are negative. The voltage level of the auxiliary reference voltage source GND is a ground voltage level. The voltage levels of the first reference voltage VGH and the auxiliary reference voltage sources VGH₁ and VGH₂ are positive. The relation between these voltage levels is VGL<VGL₁<GND<VGH₁<VGH₂ <VGH. The magnitudes of the first reference voltage VGH and the second reference voltage VGL and the number of auxiliary reference voltage sources may be determined according to the practical requirements.

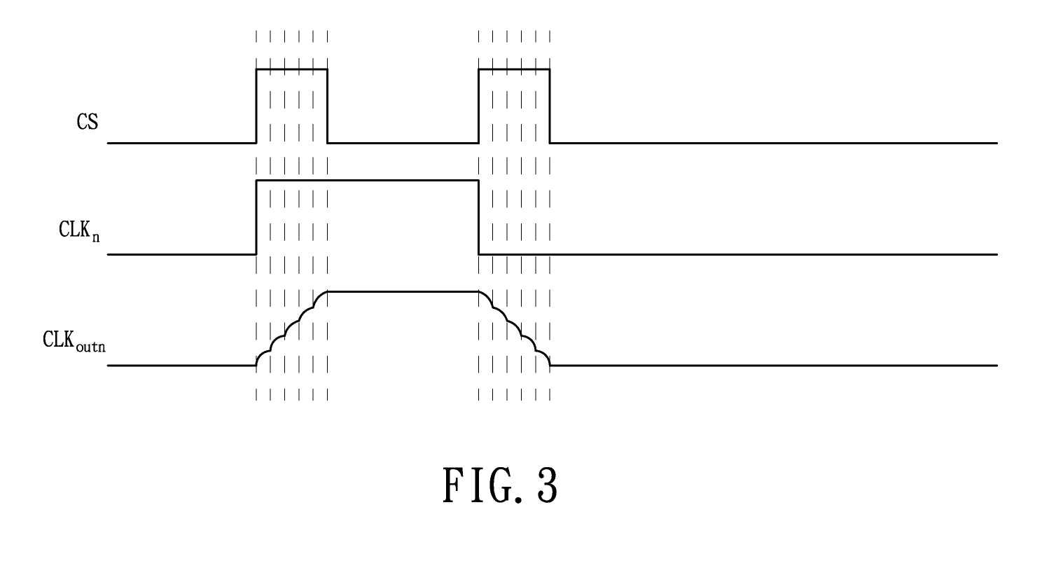

FIG. 3 is a schematic timing waveform diagram illustrating associated signals processed in the level shift unit of FIG. 2. Hereinafter, the operating principles of the level shift unit of the present invention will be illustrated with reference to FIGS. 2 and 3.

In particular, in a case that the clock-pulse input signal CLKₙ received by the amplifier 210 of the level shift unit 200 is at a low voltage-level state, the second reference voltage VGL received by the negative power terminal is outputted from the amplifier 210. Meanwhile, the control switch S₁ of the controlling circuit 220 is turned on. Consequently, the clock-pulse output signal CLKₒᵤₜₙ outputted from the output terminal 221 of the controlling circuit 220 is the second reference voltage VGL received by the negative power terminal.

In a case that the clock-pulse input signal CLKₙ is switched from the low voltage-level state to a high voltage-level state, the controlling circuit 220 is controlled according to the control signal CS such that the control switch S₁ is turned off but the auxiliary control switch S₅ is turned on. In such way, the output terminal 221 of the controlling circuit 220 shares charges with the auxiliary reference voltage source VGL₁, so that the voltage level of the clock-pulse output signal CLKₒᵤₜₙ is pulled up from the second reference voltage VGL to the voltage level VGL₁. Next, under control of the control signal CS, the auxiliary control switch S₅ is turned off but the auxiliary control switch S₄ is turned on. In such way, the output terminal 221 of the controlling circuit 220 shares charges with the auxiliary reference voltage source GND, so that the voltage level of the clock-pulse output signal CLKₒᵤₜₙ is pulled up from the voltage level VGL₁ to the voltage level GND. The rest may be deduced by analogy. That is, after the auxiliary control switch S₄ is turned off but the auxiliary control switch S₃ is turned on, the voltage level of the clock-pulse output signal CLKₒᵤₜₙ is pulled up from the voltage level GND to the voltage level VGH₁. After the auxiliary control switch S₃ is turned off but the auxiliary control switch S₂ is turned on, the voltage level of the clock-pulse output signal CLKₒᵤₜₙ is pulled up from the voltage level VGH₁ to the voltage level VGH₂. After the auxiliary control switch S₂ is turned off but the control switch S₁ is turned on again, the voltage level of the clock-pulse output signal CLKₒᵤₜₙ outputted from output terminal 221 of the controlling circuit 220 is pulled up from the voltage level VGH₂ to the first reference voltage VGH (see FIG. 3).

That is, the auxiliary control switches S₂˜S₅ and the control switch S₁ are successively turned on under control of the control signal CS. Accordingly, the clock-pulse output signal CLKₒᵤₜₙ successively and respectively shares charges with the second reference voltage VGL and the auxiliary reference voltage sources VGL₁, GND, VGH₁ and VGH₂. The voltage level of the clock-pulse output signal CLKₒᵤₜₙ is pulled up to the first reference voltage VGH and maintained at the first reference voltage VGH. Moreover, the voltage levels of the auxiliary reference voltage sources VGL₁, GND, VGH₁ and VGH₂ also constitute a part of the clock-pulse output signal CLKₒᵤₜₙ. In this embodiment, the clock-pulse output signal CLKₒᵤₜₙ is not abruptly pulled up to the first reference voltage VGH. Whereas, since the clock-pulse output signal CLKₒᵤₜₙ successively and respectively shares charges with the second reference voltage VGL and the auxiliary reference voltage sources VGL₁, GND, VGH₁ and VGH₂, the voltage level of the clock-pulse output signal CLKₒᵤₜₙ is stepwise pulled up to the first reference voltage VGH. Under this circumstance, the power consumption is very low.

On the other hand, in a case that the clock-pulse input signal CLKₙ is switched from the high voltage-level state to the high voltage-level state, the control switch S₁ and the auxiliary control switches S₂˜S₅ of the controlling circuit 220 are controlled according to the control signal CS to successively perform the following procedures: turning on the control switch S₁, turning off the control switch S₁ but turning on the auxiliary control switch S₂, turning off the auxiliary control switch S₂ but turning on the auxiliary control switch S₃, turning off the auxiliary control switch S₃ but turning on the auxiliary control switch S₄, turning off the auxiliary control switch S₄ but turning on the auxiliary control switch S₅and turning off the auxiliary control switch S₅ but turning on the control switch S₁ again. In such way, the output terminal 221 of the controlling circuit 220 successively and respectively shares charges with the second reference voltage VGL and the auxiliary reference voltage sources VGL₁, GND, VGH₁ and VGH₂. Consequently, the voltage level of the clock-pulse output signal CLKₒᵤₜₙ is stepwise pulled down to the second reference voltage VGL.

That is, the level shifter of the present invention utilizes each level shift unit to amplify each clock-pulse input signal (CLK₁˜CLKₙ) and shares charges by plural auxiliary reference voltage sources to obtain a corresponding clock-pulse output signal (CLKₒᵤₜ₁˜CLKₒᵤₜₙ). Since the clock-pulse output signal (CLKₒᵤₜ₁˜CLKₒᵤₜₙ)successively shares charges with different auxiliary reference voltage sources (VGL₁, GND, VGH₁ and VGH₂), the voltage level is stepwise pulled up (or pulled down) without being abruptly pulled up (or pulled down). Under this circumstance, the power consumption is largely reduced and the power-saving efficacy is achieved.

It is noted that, however, those skilled in the art will readily observe that the charge-sharing technology of the present invention is used to individually process the clock-pulse input signal CLKₙ. Therefore, the level shifter of the present invention can be applied to a two-phase GOA circuit or more-phase (e.g. three-phase or four-phase) GOA circuit.

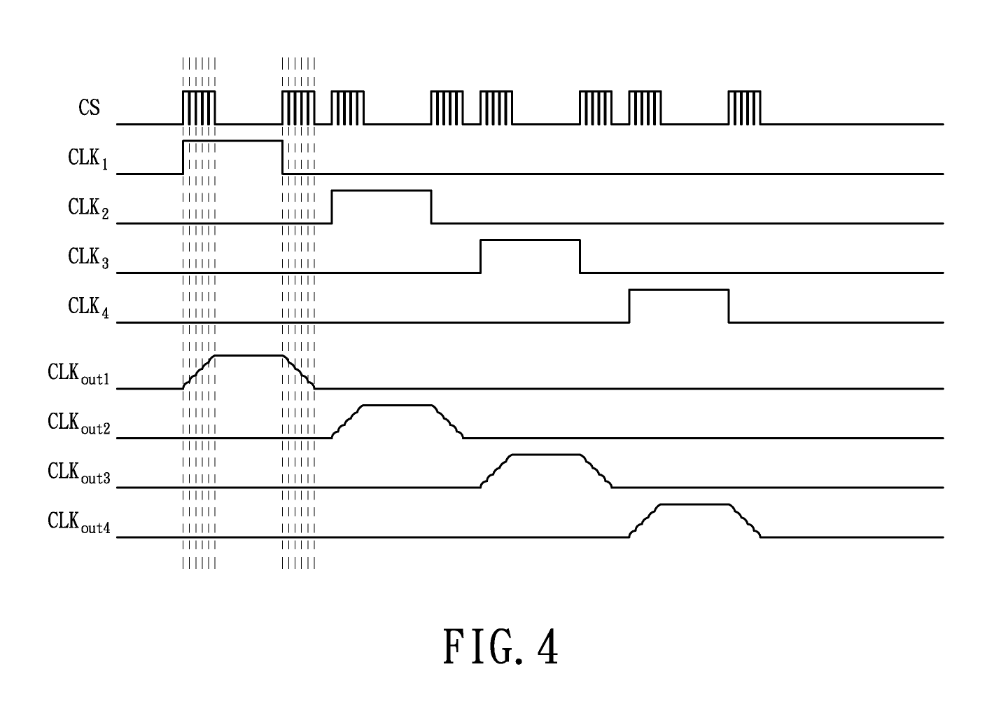

Hereinafter, a level shifter applied to a four-phase GOA circuit will be illustrated with reference to FIG. 4. FIG. 4 is a schematic timing waveform diagram illustrating associated signals processed in a level shifter of a four-phase GOA circuit according to an embodiment of the present invention. As shown in FIG. 4, four clock-pulse input signal CLK₁˜CLK₄ and a control signal CS are received by the level shifter. In addition, the four clock-pulse input signal CLK₁˜CLK₄ are processed into four corresponding clock-pulse output signals CLKₒᵤₜ₁˜CLKₒᵤₜ₄ by the level shifter. In this embodiment, the enabling periods of these four clock-pulse input signal CLK₁˜CLK₄ are not overlapped with each other. Consequently, the enabling periods of these four corresponding clock-pulse output signals CLKₒᵤₜ₁˜CLKₒᵤₜ₄ are not overlapped with each other. Moreover, during each of the clock-pulse output signals CLKₒᵤₜ₁˜CLKₒᵤₜ₄ is switched between the high voltage-level state and the low voltage-level state, the voltage level is pulled up or pulled down according to the charge-sharing technology described in FIGS. 2 and 3.

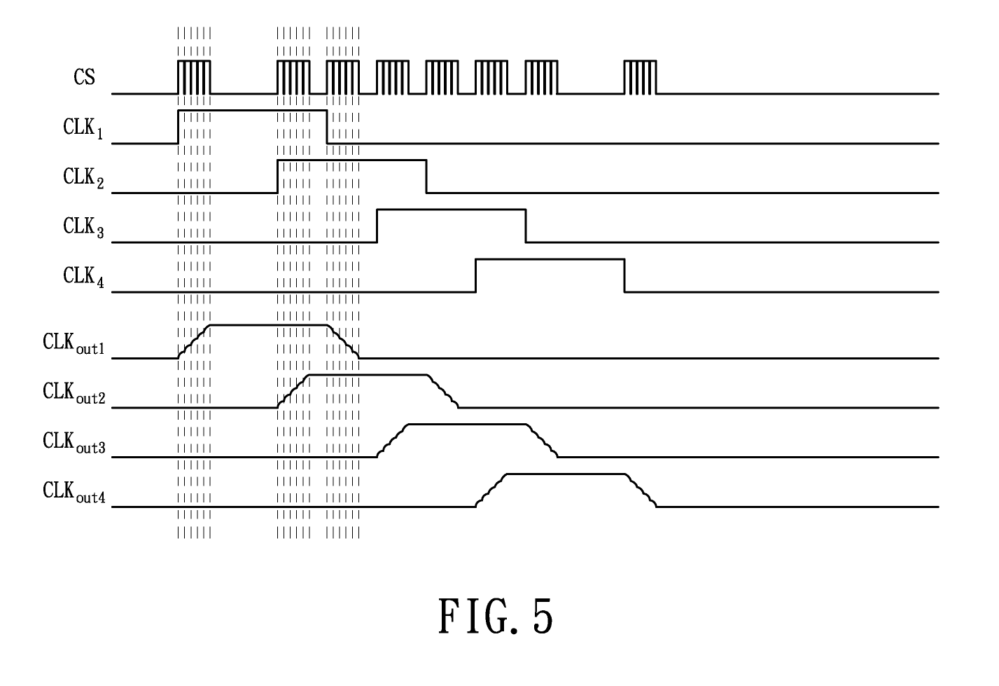

FIG. 5 is a schematic timing waveform diagram illustrating associated signals processed in a level shifter of a four-phase GOA circuit according to another embodiment of the present invention. In comparison with FIG. 4, the enabling periods of these four clock-pulse input signal CLK₁˜CLK₄ are partially overlapped with each other according to this embodiment. Consequently, the enabling periods of these four corresponding clock-pulse output signals CLKₒᵤₜ₁˜CLKₒᵤₜ₄ are also partially overlapped with each other.

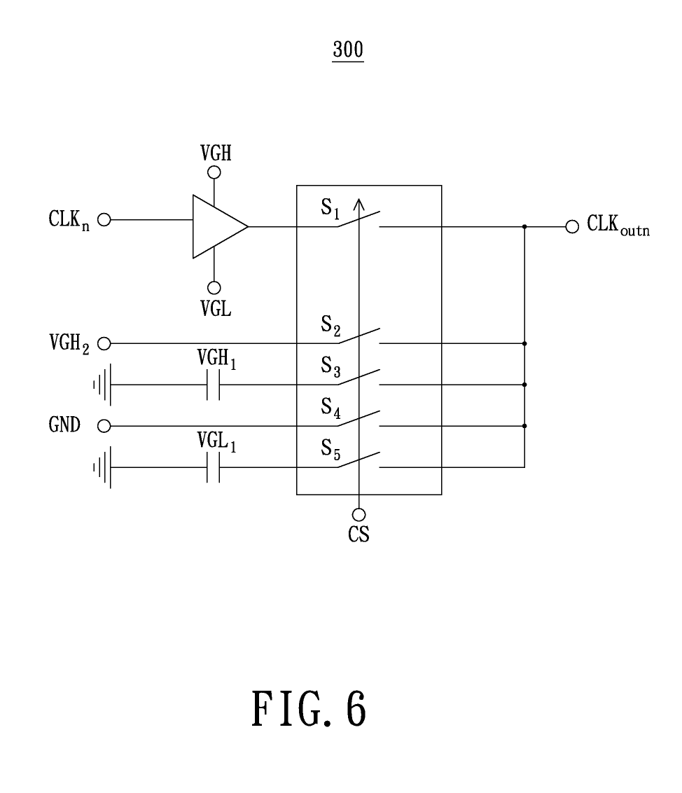

It is noted that, however, those skilled in the art will readily observe that the first reference voltage VGH, the second reference voltage VGL and the auxiliary reference voltage sources (VGL₁, GND, VGH₁ and VGH₂) may be provided by exclusive circuits such as charge pumps. Alternatively, these voltages may be provided by known circuits. FIG. 6 is a schematic circuit diagram illustrating another exemplary level shift unit of the present invention. The configurations of the level shift unit 300 of FIG. 6 are substantially identical to those of the level shift unit 200 of FIG. 2 except that the auxiliary reference voltage sources VGH₁ and VGL₁ are provided by floating capacitors, which may be physical capacitors or parasitic capacitors of the flat display device.

From the above description, the level shifter of the present invention utilizes each level shift unit to amplify the clock-pulse input signal and shares charges by plural auxiliary reference voltage sources to obtain a corresponding clock-pulse output signal. Since the clock-pulse output signal successively shares charges with different auxiliary reference voltage sources, the power consumption is largely reduced and the power-saving efficacy is achieved. Moreover, since the level shifter and the charge-sharing technology of the present invention can be applied to a two-phase GOA circuit or more-phase (e.g. three-phase or four-phase) GOA circuit, the applications of the present invention are broadened.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A level shifter comprising at least one level shift unit for generating a corresponding clock-pulse output signal, the at least one level shift unit comprising:
an amplifier comprising an input terminal for receiving a clock-pulse input signal, a positive power terminal for receiving a first reference voltage, a negative power terminal for receiving a second reference voltage, and an output terminal, wherein the first reference voltage is higher than the second reference voltage; and
a controlling circuit for outputting the clock-pulse output signal from an output terminal of the controlling circuit, wherein the controlling circuit comprises:
a control switch electrically coupled between the output terminal of the amplifier and the output terminal of the controlling circuit; and
plural auxiliary control switches electrically coupled between respective auxiliary reference voltage sources and the output terminal of the controlling circuit,
wherein the control switch and the plural auxiliary control switches are turned on at different time points according to the control signal, so that the clock-pulse output signal successively shares charges with the respective auxiliary reference voltage sources to pull up a voltage level of the clock-pulse output signal from the second reference voltage to the first reference voltage, or the clock-pulse output signal successively shares charges with the respective auxiliary reference voltage sources to pull down the voltage level of the clock-pulse output signal from the first reference voltage to the second reference voltage.

2. The level shifter according to claim 1, wherein at least one of the first reference voltage, the second reference voltage and the auxiliary reference voltage sources is provided by a corresponding floating capacitor.

3. The level shifter according to claim 1, wherein the enabling periods of plural clock-pulse output signals generated from plural level shift units are not overlapped with each other.

4. The level shifter according to claim 1, wherein the enabling periods of plural clock-pulse output signals generated from plural level shift units are partially overlapped with each other

5. A clock-pulse output signal generating method for use in a level shifter of a gate-on-array circuit, the method comprising steps of:
receiving a clock-pulse input signal; and
sharing charges between the clock-pulse output signal corresponding to the clock-pulse input signal and respective auxiliary reference voltage sources to pull up a voltage level of the clock-pulse output signal to a first reference voltage, or sharing charges between the clock-pulse output signal and the respective auxiliary reference voltage sources to pull down the voltage level of the clock-pulse output signal to a second reference voltage.

6. The clock-pulse output signal generating method according to claim 5, wherein at least one of the first reference voltage, the second reference voltage and the auxiliary reference voltage sources is provided by a corresponding floating capacitor.

7. A flat display device, comprising:
a timing controller for generating a control signal and at least one clock-pulse input signal;
a level shifter for receiving the control signal and the at least one clock-pulse input signal, and generating at least one clock-pulse output signal corresponding to the at least one clock-pulse input signal; and
a gate-on-array shift register for receiving the at least one clock-pulse output signal, thereby generating plural gate driving pulses,
wherein the level shifter comprises at least one level shift unit, and each level shift unit comprises:
an amplifier comprising an input terminal receiving a corresponding clock-pulse input signal of the at least one clock-pulse input signal, a positive power terminal receiving a first reference voltage, a negative power terminal receiving a second reference voltage, and an output terminal; and
a controlling circuit for outputting the clock-pulse output signal from an output terminal of the controlling circuit, wherein the controlling circuit comprises a control switch electrically coupled between the output terminal of the amplifier and the output terminal of the controlling circuit, and plural auxiliary control switches electrically coupled between respective auxiliary reference voltage sources and the output terminal of the controlling circuit, wherein the control switch and the plural auxiliary control switches are turned on at different time points according to the control signal, so that the clock-pulse output signal successively shares charges with the respective auxiliary reference voltage sources to pull up a voltage level of the clock-pulse output signal from the second reference voltage to the first reference voltage, or the clock-pulse output signal successively shares charges with respective auxiliary reference voltage sources to pull down the voltage level of the clock-pulse output signal from the first reference voltage to the second reference voltage.

8. The flat display device according to claim 7, wherein the enabling periods of plural clock-pulse output signals generated from plural level shift units are not overlapped with each other.

9. The flat display device according to claim 7, wherein the enabling periods of plural clock-pulse output signals generated from plural level shift units are partially overlapped with each other.
